(19) United States
(12) Patent Application Publication
(10) Pub. No.: US 2025/0020732 A1
(43) Pub. Date: Jan. 16, 2025

(54) Testing Apparatuses for Testing Battery Cells in Rest Status

(71) Applicant: SES (Shanghai) Co. Ltd., Shanghai (CN)

(72) Inventors: Yong Duan, Shanghai (CN); Zhen Liu, Shanghai (CN); Weijie Mai, Shanghai (CN)

(21) Appl. No.: 18/770,731

(22) Filed: Jul. 12, 2024

Related U.S. Application Data
(60) Provisional application No. 63/526,726, filed on Jul. 14, 2023.

(51) Int. Cl. G01R 31/396; G01R 31/389; H01M 10/42; H01M 10/48

(52) U.S. Cl. CPC G01R 31/396; G01R 31/389; H01M 10/4285; H01M 10/482; H01M 10/486

(57) ABSTRACT

In some embodiments, battery-cell testing apparatuses that each include at least one cell slot for receiving a corresponding battery cell along an insertion axis in a direction parallel to the width axis of the cell, a positive electrical contact, and a negative electrical contact. The positive and negative electrical contacts may be located and configured so that as the battery cell is inserted into the cell slot, a positive electrical tab of the cell makes physical contact with the positive electrical contact and a negative electrical tab of the cell makes physical contact with the negative electrical contact. In some embodiments, the cell slot further comprises at least one cell receiver that slidingly receives the battery cell and holds the battery cell during testing. In some embodiments, each of the positive and negative electrical contacts comprises a tab receiver.

### RELATED APPLICATION DATA

This application claims the benefit of priority of U.S. Provisional Patent Application Ser. No. 63/526,726, filed Jul. 14, 2023, and titled “Testing Apparatuses for Testing Battery Cells in Rest Status”, which is incorporated herein by reference in its entirety for all purposes.

### FIELD OF THE DISCLOSURE

The present invention generally relates to the field of testing of battery cells. In particular, the present invention is directed to testing apparatuses for testing battery cells in rest status.

### BACKGROUND

Battery cells, such as pouch cells, should be tested and monitored while in rest status, also known as storage status and warehousing status, in which no charging and discharging is occurring in order to determine the behavior of each cell. One type of rest-status test is internal electrical resistance testing in which electrical test pins or clips are contacted with corresponding respective ones of the positive and negative electrical tabs of a battery cell, measurement data is collected, and then the test pins or test clips are removed from the electrical tabs. Typically, the testing proceeds one cell at a time. Another type of rest-status test is a surface temperature test in which a thermocouple is thermally coupled to a test point on a cell using a thermally conductive gel, and measurement data is collected and displayed on multichannel temperature acquisition equipment.

### SUMMARY OF THE DISCLOSURE

In an implementation, the present disclosure is directed to an apparatus for testing a battery cell that includes a stack region having first and second lateral sides spaced from one another along a width axis, first and second ends spaced from one another in a direction perpendicular to the width axis, a positive electrical tab projecting away from the stack region at the first end and a negative electrical tab projecting away from the stack region at the second end. The apparatus includes a cell slot for receiving the battery cell along an insertion axis in a direction parallel to the width axis of the battery cell; a positive electrical contact; and a negative electrical contact; wherein the positive and negative electrical contacts are located and configured so that as the battery cell is inserted into the cell slot along the width axis of the battery cell, the positive electrical tab makes physical contact with the positive electrical contact by way of the lateral edge of the positive electrical tab and the negative electrical tab makes physical contact with the negative electrical contact by way of the lateral edge of the negative electrical tab.

### BRIEF DESCRIPTION OF THE DRAWINGS

For the purpose of illustration, the accompanying drawings show aspects of one or more embodiments of the disclosure. However, it should be understood that the scope of this disclosure is not limited to the precise arrangements and instrumentalities shown in the drawings, wherein:

FIG. 1A is an isometric end view of an example battery-cell testing apparatus made in accordance with the present disclosure, showing the sidewall closest to the viewer removed to reveal internal structure;

FIG. 1B is an isometric top view of the example testing apparatus of FIG. 1A;

FIG. 1C is a top-down view of the example testing apparatus of FIGS. 1A and 1B, showing portions of the electrical contacts for receiving the electrical tabs of the cells;

FIG. 1D is a reduced-size isometric view of the example testing apparatus of FIGS. 1A through 1C, showing an example of how temperature sensors can be applied to a battery cell contained in the battery-cell testing apparatus;

FIG. 1E(1) is an enlarged isometric view of one of the tab receivers of the testing apparatus of FIGS. 1A through 1D;

FIG. 1E(2) is an isometric view of the tab receiver of FIG. 1E(1), showing the housing removed;

FIG. 1E(3) is an enlarged view of an end of one of the cell slots of the example testing apparatus of FIGS. 1A through 1D, showing the electrical contact block of one of the tab receivers in an extended position when a cell is not present in the cell slot;

FIG. 1E(4) is an isometric view of the end of the cell slot shown in FIG. 1E(3), showing the contact block in a depressed position under influence of the cell in the cell slot;

FIG. 2A is a side view of an example pouch-type battery cell that can be tested in a battery-cell testing apparatus of the present disclosure; and

FIG. 2B is an enlarged end view of the example pouch-type battery cell of FIG. 2A.

### DETAILED DESCRIPTION

The entire content of the appended claims is incorporated into this Detailed Description section as if originally presented herein.

In some aspects, the present disclosure is directed to testing apparatuses designed and configured to test battery cells (hereinafter, simply “cells”), such as pouch cells, of any suitable electrochemistry, such as, but not limited to, lithium (Li)-metal electrochemistry and Li-ion electrochemistry, among others, including cells using liquid electrolyte, gel electrolyte, or solid electrolyte, or any combination or subcombination thereof. In some embodiments, the testing apparatus is configured to test at least one, and in many cases more than one, cell using at least one type of testing, such as an internal resistance testing or surface-temperature testing, or both, among others. Typically, a testing apparatus of the present disclosure is designed and configured to perform testing (e.g., data collection) while each cell is in a rest status, i.e., when the cell is not being charged or discharged.

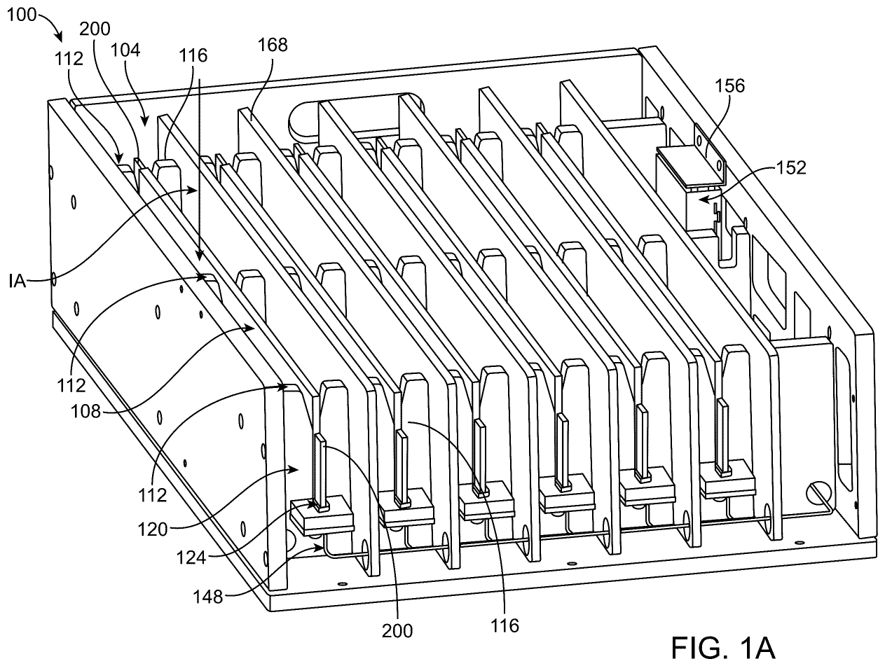

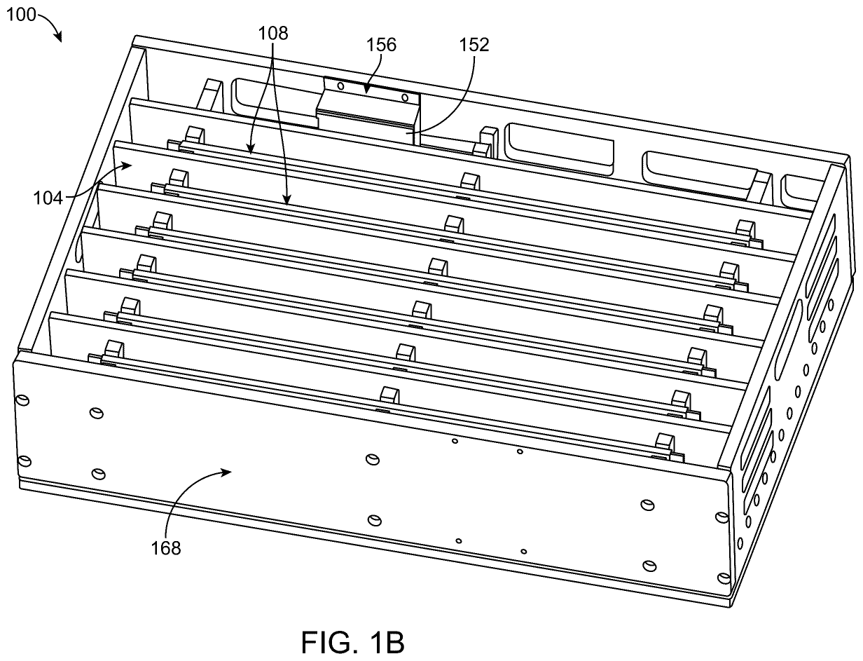

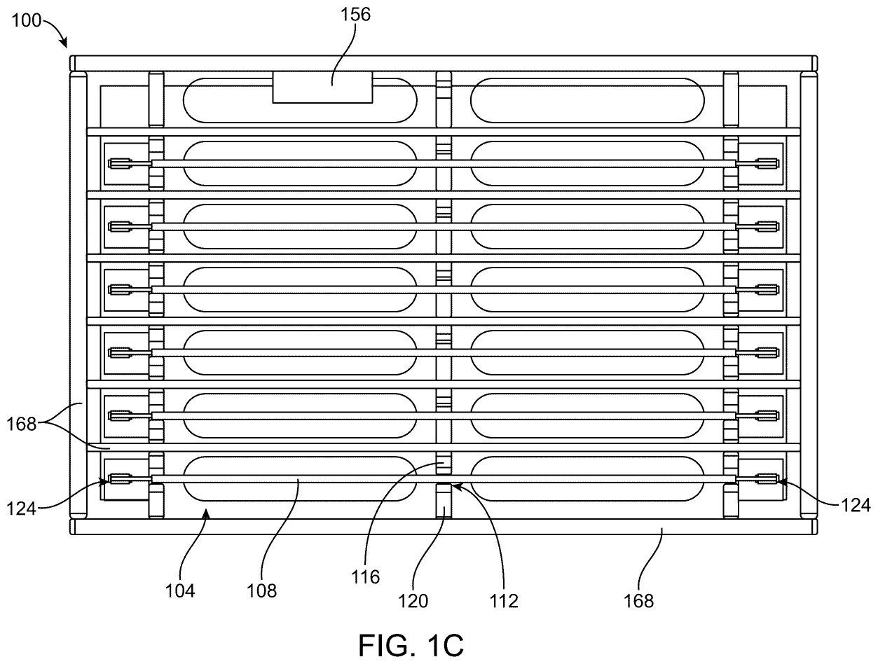

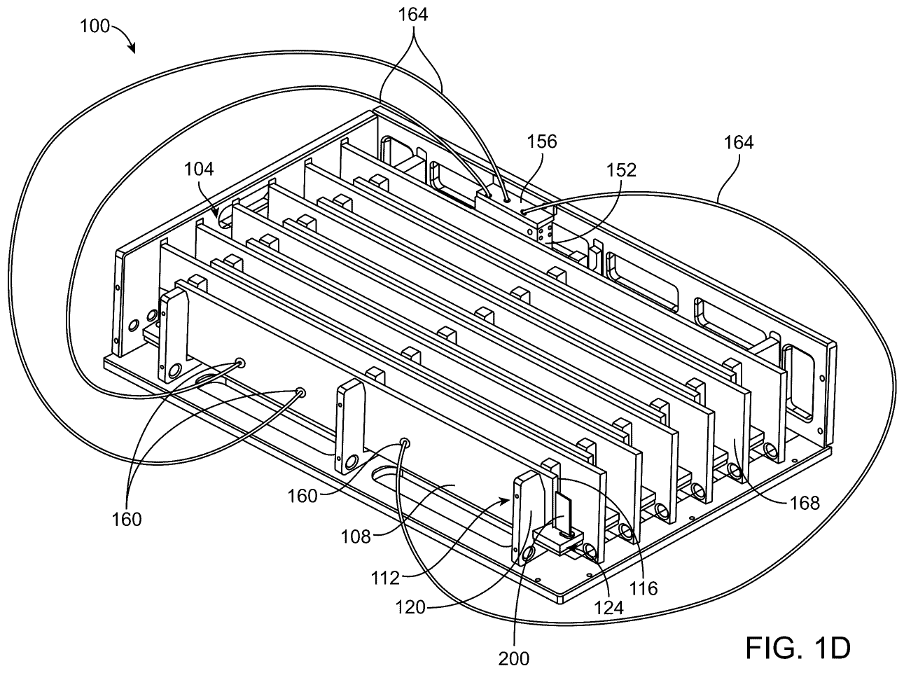

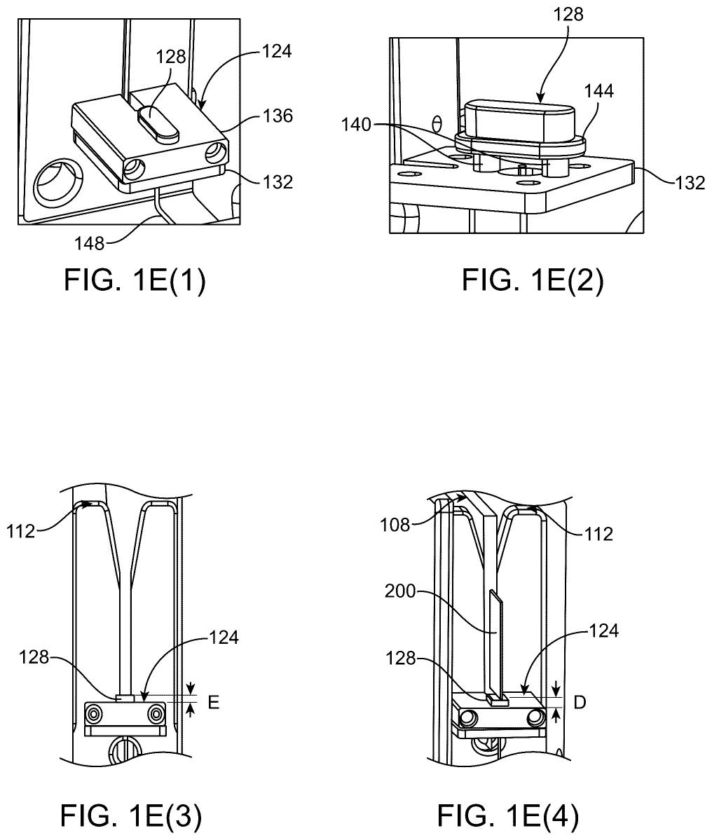

FIGS. 1A through 1E(4) illustrate an example testing apparatus 100 made in accordance with the present disclosure. In this example, the testing apparatus 100 includes a plurality of cell slots, here six cell slots 104, for receiving and testing a corresponding plurality of cells 108, here six cells 108 (not all are labeled). More or fewer cell slots 104 can be provided depending on the particular design requirements. It is also noted that the cells 108 shown are merely examples and that other cells may vary in one or more ways, such as, but not limited to, being longer or shorter, being thicker or thinner, being wider or narrower, or having different electrical tab configurations, among others, and any combination or sub-combination thereof.

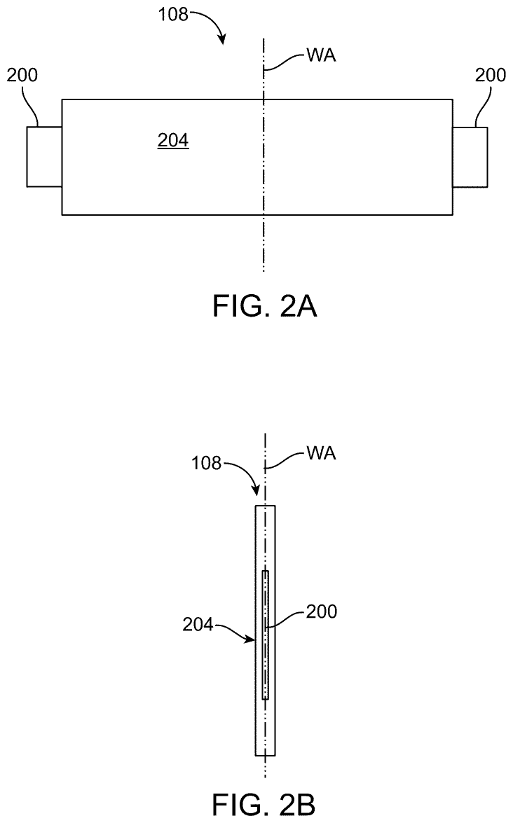

FIGS. 2A and 2B illustrate an example cell type that the cell 108 of FIGS. 1A through 1D can be. In this example, the cell 108 is a pouch-type cell having the general configuration shown with positive and negative electrical tabs 200 located at opposite ends of a stack region 204. As those of ordinary skill in the art will readily understand, the stack region 204 is the part of the cell 108 that contains one or more of each of multiple differing layers, such as anode(s), separator(s), cathode(s), among other possible layers, and one or more electrolytes (e.g., as a liquid, a gel, a solid, or any suitable combination thereof) that provide the electrochemical energy storage capability of the cell 108. FIGS. 2A and 2B also show a width axis WA referred to below in describing operation of the testing apparatus. In this example, the width axis WA extends parallel to the width of the cell 108, with the length of the cell 108 extending along an axis perpendicular to the width axis WA and extending between the two tabs 200.

Referring back to FIGS. 1A through 1E(4), each cell slot 104 includes at least one cell receiver, here three cell receivers 112, that slidingly receive a corresponding one of the cells 108 and hold the cell fixed during testing. In this example, each cell receiver 112 has a guiding region 116 and a holding region 120, with the cell-guiding region having one or more sloped surfaces that guide a cell 108 into engagement with the holding region. The holding region 120 may be designed to frictionally engage lateral faces of the cell 108 so that little to no play exists between the cell and the holding region of the cell receiver 112. In some embodiments, each sloped surface of the cell-guiding region 116 forms an angle relative to vertical from about 10° to about 45°, though other angles can be used. In the example shown, each side of the cell-guiding region 116 forms an angle of about 30° relative to vertical.

In this example, each cell slot 104 includes a tab receiver 124 located at each end of the cell slot. Each tab receiver 124 is designed and configured to make electrical contact with a corresponding electrical tab 200 (hereinafter, simply “tab”) on a cell 108 when the cell is fully inserted into the cell slot 104. It is noted that FIG. 1A shows the tab receiver 124 at the end of each cell slot 104 closest to the viewer of FIG. 1A. A like tab receiver 124 is located in a mirrored orientation at the opposite end of each cell slot 104. Referring particularly to FIG. 1E(1), in the example shown each tab receiver 124 includes a contact block 128, a base 132, and a housing 136. The contact block 128 may be made of an electrically conductive material, such as copper, aluminum, etc., and each of the base 132 and housing 136 may be made of a dielectric material, such as any suitable plastic. As seen in FIG. 1E(2), the contact block 128 is engaged by one or more springs (here, two springs 140), which bias it into an extended position having an extended distance, E, measured from the top of the housing 136 to the upper surface of the contact block 128 as illustrated in FIG. 1E(3). The contact block 128 includes a flange 144 that the springs 140 bias into contact with the underside of the upper wall of the housing 136 when the contact block 128 is in its extended position. In the example shown, the extended distance E is about 3 mm, although it may be larger or smaller depending on the design. In this example, the weight of a cell 108 within the relevant cell slot 104 causes the tab 200 on the cell 108 to compress the springs 140 under the contact block 128 so as to push the contact block down to a depressed position having a depressed distance, D, measured from the top of the housing 136 to the upper surface of the contact block as illustrated in FIG. 1E(4). FIG. 1E(1) also shows a wire 148 extending from beneath the tab receiver 124. This wire 148 electrically connects the contact block 128 to electronics, such as the central electronics 152 described below.

In other embodiments, a tab receiver 124 may include a tab slot (not shown) for slidingly receiving the bottom portion of a corresponding tab 200 at the bottom edge of that tab. At least some of the portions of the tab receiver 124 that contact the tab 200 are made of one or more electrically conductive materials, such as metals, so that electricity can flow between such portions and the tab, for example, during internal electrical resistance testing. In some embodiments, the tab slot may be eliminated, with only the bottom edge of a tab 200 engaging the tab receiver 124 and the contact block 128.

As discussed above, each tab receiver 124 may include a biasing means, such as a coil spring, leaf spring, foam pad, rubber band, etc., that biases the tab receiver upward to a position above its position when the corresponding cell 108 is fully inserted into the relevant cell slot 104. In this manner, physical contact between the tab 200 and the tab receiver 124 can be guaranteed, because the act of fully inserting the cell 108 into the cell slot 104 would work against the biasing means, thereby causing the tab receiver to remain in forceable engagement with the tab when the cell is fully inserted into the cell slot. In some embodiments, the biasing force for each tab receiver 124 can be designed and selected so that the tab receiver moves under the influence of only the weight of the cell 108. In some embodiments, the biasing force for each tab receiver 124 can be designed and selected so that the tab receiver moves only when the cell 108 is pushed into full engagement with the cell slot 104. In this latter case, friction between the cell 108 and the holding region 120 of the cell receiver 112 may keep the biasing means from moving once the cell has been fully inserted.

In the example shown in FIGS. 1A through ID, the testing apparatus 100 includes central electronics 152, mounted on a mounting block 156, that are in electrical communication with the electrical contacts and any sensors, such as the temperature sensors 160 shown in FIG. 1D, that are located onboard the testing apparatus 100. The central electronics 152 may include, among other things, data-collection electronics/software, testing-control electronics/software, one or more communications ports (e.g., a wireless communications port (radio (e.g., BLUETOOTH®, infrared, etc.) and/or wired communications port (e.g., USB, RS232, etc.)), and any communications software needed for communications, among other things. In this example, each temperature sensor 160 may be any suitable type of temperature sensor, such as, but not limited to a negative temperature coefficient (NTC) thermistor and a thermocouple, among others. In this example, three temperature sensors 160 are shown as being applied to one face of one of the six cells 108 in the testing apparatus 100, for example, using a thermal adhesive. Sensor wires 164 connect each of the three temperature sensors 160 to the central electronics 152. It is noted that more or fewer than three temperature sensors 160 may be used on any cell face of any one or more of the cells 108 in the testing apparatus 100.

In some embodiments, some or all of the walls 168 (interior and exterior) may be made of one or more materials that are robust enough to remain intact should any of the cells 108 under test explode and/or catch fire. Examples of suitable materials include, but are not limited to, any of a variety of metals, quartz, marble, and glass, among many others. Although not shown, the testing apparatus 100 may include at least one cover that closes all of the cell slots 104 so as to fully contain any explosion and/or fire that may occur in any of the cell slots.

It is noted that while the example testing apparatus of FIGS. 1A through 1D, is depicted as having a vertical insertion axis IA (FIG. 1A), the insertion axis IA may be horizontal in other embodiments, particularly embodiments wherein the cells 108 are held in place via a friction fit, such as a friction fit with the holding region 120 of each cell receiver 112 provided or a friction fit between each electrical tab 200 and tab slot, or a combination of these two friction fits. When the insertion axis IA is horizontal, the cell slots 104 may have their longitudinal axis oriented either vertically or horizontally. Of course, the insertion axis(es) IA may be oriented other than purely vertically or horizontally.

Various modifications and additions can be made without departing from the spirit and scope of this disclosure. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve aspects of the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. An apparatus for testing a battery cell that includes a stack region having first and second lateral sides spaced from one another along a width axis, first and second ends spaced from one another in a direction perpendicular to the width axis, a positive electrical tab projecting away from the stack region at the first end and a negative electrical tab projecting away from the stack region at the second end, the apparatus comprising:
a cell slot for receiving the battery cell along an insertion axis in a direction parallel to the width axis of the battery cell;
a positive electrical contact; and
a negative electrical contact;
wherein the positive and negative electrical contacts are located and configured so that as the battery cell is inserted into the cell slot along the width axis of the battery cell, the positive electrical tab makes physical contact with the positive electrical contact by way of the lateral edge of the positive electrical tab and the negative electrical tab makes physical contact with the negative electrical contact by way of the lateral edge of the negative electrical tab.

2. The apparatus of claim 1, wherein the cell slot further comprises at least one receiver that slidingly receives the battery cell and holds the battery cell during testing.

3. The apparatus of claim 2, wherein the at least one cell receiver includes a holding region and a guiding region for guiding the battery cell into the holding region.

4. The apparatus of claim 3, wherein the guiding region includes at least one sloped surface designed and configured to guide the battery cell along the insertion axis as the battery cell is inserted into the cell slot.

5. The apparatus of claim 3, wherein the holding region is designed and configured to hold the battery cell by friction.

6. The apparatus of claim 1, wherein each of the positive and negative electrical contacts is biased by a biasing mechanism in a direction parallel to the insertion axis so that, when the battery cell is inserted into the cell slot, continued insertion of the battery cell compresses the biasing mechanism.

7. The apparatus of claim 6, wherein the biasing mechanism comprises at least one spring.

8. The apparatus of claim 6, wherein the biasing mechanism remains compressed by weight of the battery cell.

9. The apparatus of claim 6, wherein the biasing mechanism remains compressed by friction fit of the battery cell with lateral guides designed and configured to guide the battery cell along the insertion axis as the battery cell is inserted into the cell slot.

10. The apparatus of claim 6, wherein the biasing mechanism remains compressed by friction fit of the battery cell with clamps of the positive and negative electrical contacts.

11. The apparatus of claim 1, wherein each of the positive and negative electrical contacts comprises a tab receiver.

12. The apparatus of claim 11, wherein each tab receiver has a tab slot for receiving a lower portion of a corresponding one of the electrical tabs.

13. The apparatus of claim 12, wherein each tab slot provides a friction fit between the tab receiver and the corresponding one of the electrical tabs.

14. The apparatus of claim 1, further comprising a temperature probe for measuring a temperature of the stack region of the battery cell.

15. The apparatus of claim 1, further comprising central electronics that collects data from the cell slot, wherein each of the positive and negative electrical contacts is in operative communication with the central electronics.

16. The apparatus of claim 15, wherein the central electronics includes a wireless radio for transmitting the collected data to an offboard device.

17. The apparatus of claim 1, further comprising a plurality of the cell slots, wherein each cell slot includes one each of the positive and negative electrical contacts.

18. The apparatus of claim 17, wherein the plurality of cell slots are arranged side-by-side, with adjacent ones of the cell slots separated by a fireproof wall.

19. The apparatus of claim 17, further comprising central electronics that collects data from the cell slots, wherein each of the positive and negative electrical contacts of the plurality of cell slots is in operative communication with the central electronics.

20. The apparatus of claim 19, wherein the central electronics includes a wireless radio for transmitting the collected data to an offboard device.

21. The apparatus of claim 17, wherein each of the cell slots includes a temperature probe for measuring a temperature of the stack region of the battery cell contained in the cell slot, wherein each of the temperature probes is in operative communication with the central electronics.
